(19) United States
(12) Patent Application Publication
(10) Pub. No.: US 2024/0098989 A1
(43) Pub. Date: Mar. 21, 2024

(54) THREE-DIMENSIONAL MEMORY DEVICES AND METHODS FOR FORMING THE SAME

(71) Applicant: YANGTZE MEMORY TECHNOLOGIES CO., LTD., Wuhan (CN)

(72) Inventors: Zhengliang Xia, Wuhan (CN); Wenbin Zhou, Wuhan (CN); Zongliang Huo, Wuhan (CN); Zhaohui Tang, Wuhan (CN)

(21) Appl. No.: 17/948,549

(22) Filed: Sep. 20, 2022

(51) Int. Cl. H01L 27/11556; H01L 27/11519; H01L 27/11526; H01L 27/11565; H01L 27/11573; H01L 27/11582

(52) U.S. Cl. CPC H01L 27/11556; H01L 27/11519; H01L 27/11526; H01L 27/11565; H01L 27/11573; H01L 27/11582

(57) ABSTRACT

A semiconductor device includes a plurality of memory blocks. Each memory block includes a memory deck including interleaved first conductor layers and first dielectric layers, and a separation structure extending to separate two adjacent memory blocks. Each separation structure includes a dielectric stack including interleaved third dielectric layers and fourth dielectric layers. The third dielectric layers are in contact with the first dielectric layers, and the fourth dielectric layers are in contact with the first conductor layers.

### BACKGROUND

The present disclosure relate to three-dimensional (3D) memory devices and fabrication methods thereof.

Planar memory cells are scaled to smaller sizes by improving process technology, circuit design, programming algorithm, and fabrication process. However, as feature sizes of the memory cells approach a lower limit, planar process and fabrication techniques become challenging and costly. As a result, memory density for planar memory cells approaches an upper limit. As the number of 3D memory layers continues to increase, the control of channel profiles becomes more and more difficult.

### SUMMARY

3D memory devices and methods for forming the same are disclosed herein.

In one aspect, a semiconductor device is disclosed. The semiconductor device includes a plurality of memory blocks and a separation structure extending to separate two adjacent memory blocks. Each memory block includes a memory deck including interleaved first conductor layers and first dielectric layers. Each separation structure includes a dielectric stack including interleaved third dielectric layers and fourth dielectric layers. The third dielectric layers are in contact with the first dielectric layers, and the fourth dielectric layers are in contact with the first conductor layers.

In some implementations, the memory deck includes a first memory deck including interleaved first conductor layers and first dielectric layers, and a second memory deck including interleaved second conductor layers and second dielectric layers above the first memory deck.

In some implementations, the semiconductor device further includes a first channel structure extending through the first memory deck, the first channel structure comprising a first memory film and a first semiconductor channel; and a second channel structure extending through the second memory deck, the second channel structure comprising a second memory film and a second semiconductor channel. The second semiconductor channel is in contact with the first semiconductor channel.

In some implementations, the first memory film includes a tunneling layer over the first semiconductor channel, a storage layer over the tunneling layer, and a blocking layer over the storage layer. The storage layer is divided by the first dielectric layers into a plurality of sections.

In some implementations, the second memory film includes a tunneling layer over the second semiconductor channel, a storage layer over the tunneling layer, and a blocking layer over the storage layer. The storage layer is divided by the second dielectric layers into a plurality of sections.

In some implementations, the semiconductor device further includes a peripheral circuit disposed above or beneath the plurality of memory blocks.

In some implementations, the first conductor layers include a first portion near the separation structure and a second portion away from the separation structure, and the first portion and the second portion have a same thickness.

In some implementations, the first dielectric layers include a first portion near the separation structure and a second portion away from the separation structure, and a thickness different between the first portion and the second portion is less than 1 nanometer.

In another aspect, a system is disclosed. The system includes a semiconductor device configured to store data, and a memory controller coupled to the semiconductor device and configured to control operations of the semiconductor device. The semiconductor device includes a plurality of memory blocks and a separation structure extending to separate two adjacent memory blocks. Each memory block includes a memory deck including interleaved first conductor layers and first dielectric layers. Each separation structure includes a dielectric stack including interleaved third dielectric layers and fourth dielectric layers. The third dielectric layers are in contact with the first dielectric layers, and the fourth dielectric layers are in contact with the first conductor layers.

In still another aspect, a method for forming a semiconductor device is disclosed. A dielectric stack including interleaved first dielectric layers and second dielectric layers is formed. A first opening is formed extending in the dielectric stack. The first dielectric layers are replaced with a plurality of word lines through the first opening. A plurality of channel structures are formed in the first opening.

In some implementations, a first dielectric stack including interleaved first dielectric layers and second dielectric layers is formed. A first sacrificial structure and a second sacrificial structure are formed extending in the first dielectric stack. A second dielectric stack including interleaved first dielectric layers and second dielectric layers is formed over the first dielectric stack.

In some implementations, the dielectric stack includes the first dielectric stack and the second dielectric stack.

In some implementations, the first sacrificial structure and a portion of the second dielectric stack above the first sacrificial structure are removed to form a second opening. A third sacrificial structure is formed in the first opening extending in the first dielectric stack and the second dielectric stack. The second sacrificial structure and a portion of the second dielectric stack above the second sacrificial structure are removed to form the first opening.

In some implementations, the third sacrificial structure is removed to form a plurality of third openings. The plurality of channel structures are formed in the plurality of third openings.

In some implementations, a fourth opening and a fifth opening are formed extending in the first dielectric stack. A third dielectric layer, a first semiconductor layer and a fourth dielectric layer are formed in the fourth opening and the fifth opening to form the first sacrificial structure and the second sacrificial structure.

In some implementations, the third dielectric layer includes a silicon oxide layer, the first semiconductor layer includes a polysilicon layer, and the fourth dielectric layer includes a silicon oxide layer.

In some implementations, a patterned mask is formed on the second dielectric stack aligning the first sacrificial structure. The portion of the second dielectric stack above the first sacrificial structure is removed. The first sacrificial structure is removed.

In some implementations, a portion of the first dielectric layers exposed by the second opening is removed.

In some implementations, a fifth dielectric layer, a second semiconductor layer, and a sixth dielectric layer are formed in the second opening.

In some implementations, the fifth dielectric layer includes a silicon oxide layer, the second semiconductor layer includes a polysilicon layer, and the sixth dielectric layer includes a silicon oxide layer.

In some implementations, the portion of the second dielectric stack aligning the second sacrificial structure is removed. The second sacrificial structure is removed.

In some implementations, a portion of the first dielectric layers is removed through the first opening to form a cavity in the first dielectric stack and the second dielectric stack. A seventh dielectric layer, a barrier layer, and a conductor layer are formed in the cavity.

In some implementations, the seventh dielectric layer, the barrier layer, and the conductor layer on sidewalls of the first opening are removed.

In some implementations, a portion of the conductor layer is removed to form a recessed structure between the second dielectric layers. The barrier layer is formed over the conductor layer. A portion of the seventh dielectric layer is removed. The conductor layer is surrounded by the barrier layer.

In some implementations, a fourth sacrificial structure is formed in the first opening extending in the first dielectric stack and the second dielectric stack. The third sacrificial structure and the fourth sacrificial structure are removed to form the plurality of third openings.

In yet another aspect, a method for forming a semiconductor device is disclosed. A first dielectric stack including interleaved first dielectric layers and second dielectric layers is formed. A second dielectric stack including interleaved first dielectric layers and second dielectric layers is formed over the first dielectric stack. A plurality of first openings are formed extending in the first dielectric stack and the second dielectric stack. A plurality of first sacrificial structures are formed in the plurality of first openings. A plurality of second openings are formed extending in the first dielectric stack and the second dielectric stack, each second opening being disposed between two first sacrificial structures. The first dielectric layers are replaced with a plurality of word lines through the plurality of second openings. A plurality of second sacrificial structures are formed in the second opening extending in the first dielectric stack and the second dielectric stack. The plurality of first sacrificial structures and the plurality of second sacrificial structures are removed to form a plurality of third openings. A plurality of channel structures are formed in the plurality of third openings.

In some implementations, a fourth opening and a fifth opening are formed extending in the first dielectric stack. A first semiconductor layer and a third dielectric layer are formed in the fourth opening and the fifth opening to form a third sacrificial structure and a fourth sacrificial structure extending in the first dielectric stack.

In some implementations, the first semiconductor layer includes a polysilicon layer, and the third dielectric layer includes a silicon oxide layer.

In some implementations, the third sacrificial structure and a portion of the second dielectric stack above the third sacrificial structure are removed to form the plurality of first openings.

In some implementations, a patterned mask is formed on the second dielectric stack aligning the third sacrificial structure. The portion of the second dielectric stack above the third sacrificial structure is removed. The third sacrificial structure is removed.

In some implementations, a fourth dielectric layer, a second semiconductor layer, and a fifth dielectric layer are formed in the plurality of first openings.

In some implementations, the fourth dielectric layer includes a silicon oxide layer, the second semiconductor layer includes a polysilicon layer, and the fifth dielectric layer includes a silicon oxide layer.

In some implementations, a portion of the second dielectric stack aligning the fourth sacrificial structure is removed. The fourth sacrificial structure is removed.

In some implementations, a portion of the first dielectric layers is removed through the plurality of second openings to form a cavity in the first dielectric stack and the second dielectric stack. A sixth dielectric layer, a barrier layer, and a conductor layer are formed in the cavity.

In some implementations, the sixth dielectric layer includes a high dielectric constant (high-k) dielectric layer, the barrier layer includes a titanium nitride layer, and the conductor layer includes a tungsten layer.

In some implementations, the sixth dielectric layer, the barrier layer, and the conductor layer on sidewalls of the plurality of second openings are removed.

In some implementations, a portion of the conductor layer is removed to form a recessed structure between the second dielectric layers. The barrier layer is formed over the conductor layer. A portion of the sixth dielectric layer is removed. The conductor layer is surrounded by the barrier layer.

### BRIEF DESCRIPTION OF THE DRAWINGS

The accompanying drawings, which are incorporated herein and form a part of the specification, illustrate aspects of the present disclosure and, together with the description, further serve to explain the present disclosure and to enable a person skilled in the pertinent art to make and use the present disclosure.

FIG. 1 illustrates a plan view of an exemplary 3D memory device, according to some aspects of the present disclosure.

FIG. 2 illustrates another plan view of an exemplary 3D memory device, according to some aspects of the present disclosure.

FIG. 3 illustrates a cross-section of an exemplary 3D memory device, according to some aspects of the present disclosure.

FIGS. 4-16 illustrate cross-sections of an exemplary 3D memory device at different stages of a manufacturing process, according to some aspects of the present disclosure.

FIGS. 17-18 illustrate plan views of an exemplary 3D memory device, according to some aspects of the present disclosure.

FIG. 19 illustrates a flowchart of an exemplary method for forming a 3D memory device, according to some aspects of the present disclosure.

FIG. 20 illustrates a flowchart of another exemplary method for forming a 3D memory device, according to some aspects of the present disclosure.

FIG. 21 illustrates a block diagram of an exemplary system having a memory device, according to some aspects of the present disclosure.

FIG. 22A illustrates a diagram of an exemplary memory card having a memory device, according to some aspects of the present disclosure.

FIG. 22B illustrates a diagram of an exemplary solid-state drive (SSD) having a memory device, according to some aspects of the present disclosure.

The present disclosure will be described with reference to the accompanying drawings.

### DETAILED DESCRIPTION

Although specific configurations and arrangements are discussed, it should be understood that this is done for illustrative purposes only. As such, other configurations and arrangements can be used without departing from the scope of the present disclosure. Also, the present disclosure can also be employed in a variety of other applications. Functional and structural features as described in the present disclosures can be combined, adjusted, and modified with one another and in ways not specifically depicted in the drawings, such that these combinations, adjustments, and modifications are within the scope of the present discloses.

In general, terminology may be understood at least in part from usage in context. For example, the term “one or more” as used herein, depending at least in part upon context, may be used to describe any feature, structure, or characteristic in a singular sense or may be used to describe combinations of features, structures or characteristics in a plural sense. Similarly, terms, such as “a,” “an,” or “the,” again, may be understood to convey a singular usage or to convey a plural usage, depending at least in part upon context. In addition, the term “based on” may be understood as not necessarily intended to convey an exclusive set of factors and may, instead, allow for existence of additional factors not necessarily expressly described, again, depending at least in part on context.

It should be readily understood that the meaning of “on,” “above,” and “over” in the present disclosure should be interpreted in the broadest manner such that “on” not only means “directly on” something but also includes the meaning of “on” something with an intermediate feature or a layer therebetween, and that “above” or “over” not only means the meaning of “above” or “over” something but can also include the meaning it is “above” or “over” something with no intermediate feature or layer therebetween (i.e., directly on something).

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations), and the spatially relative descriptors used herein may likewise be interpreted accordingly.

As used herein, the term “layer” refers to a material portion including a region with a thickness. A layer can extend over the entirety of an underlying or overlying structure or may have an extent less than the extent of an underlying or overlying structure. Further, a layer can be a region of a homogeneous or inhomogeneous continuous structure that has a thickness less than the thickness of the continuous structure. For example, a layer can be located between any pair of horizontal planes between, or at, a top surface and a bottom surface of the continuous structure. A layer can extend horizontally, vertically, and/or along a tapered surface. A substrate can be a layer, can include one or more layers therein, and/or can have one or more layer thereupon, thereabove, and/or therebelow. A layer can include multiple layers. For example, an interconnect layer can include one or more conductor and contact layers (in which interconnect lines and/or via contacts are formed) and one or more dielectric layers.

As used herein, the term “substrate” refers to a material onto which subsequent material layers are added. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically non-conductive material, such as a glass, a plastic, or a sapphire wafer.

As used herein, the term “3D memory device” refers to a semiconductor device with vertically oriented strings of memory cell transistors (referred to herein as “memory strings,” such as NAND memory strings) on a laterally-oriented substrate so that the memory strings extend in the vertical direction with respect to the substrate. As used herein, the term “vertical/vertically” means nominally perpendicular to the lateral surface of a substrate.

A 3D semiconductor device can be formed by stacking semiconductor wafers or dies and interconnecting them vertically so that the resulting structure acts as a single device to achieve performance improvements at reduced power and a smaller footprint than conventional planar processes. However, when using the slit structure opening to replace the word lines, the thickness of the word lines may be different or uneven based on the distance to the slit structure opening. The present application is introduced to overcome these deficiencies.

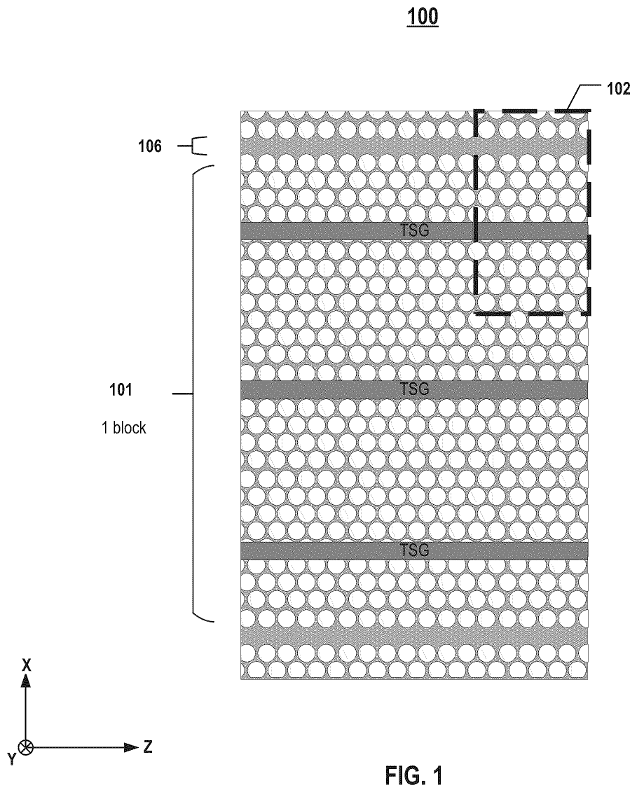

FIG. 1 illustrates a plan view of a semiconductor device. In some implementations, the semiconductor device may be an exemplary 3D memory device 100, according to some aspects of the present disclosure. As shown in FIG. 1, 3D memory device 100 is divided into a plurality of memory blocks 101 by a separation structure 106. Separation structure 106 is an isolation structure to electrically isolate adjacent memory blocks 101. In some implementations, separation structure 106 may extend along the z-direction and the y-direction. A plurality of channel structures may be formed in memory block 101 and may extend along the y-direction perpendicular to the x-direction and the z-direction. In some implementations, the x-direction may be the word lines extending direction, and the y-direction may be the memory stacking direction.

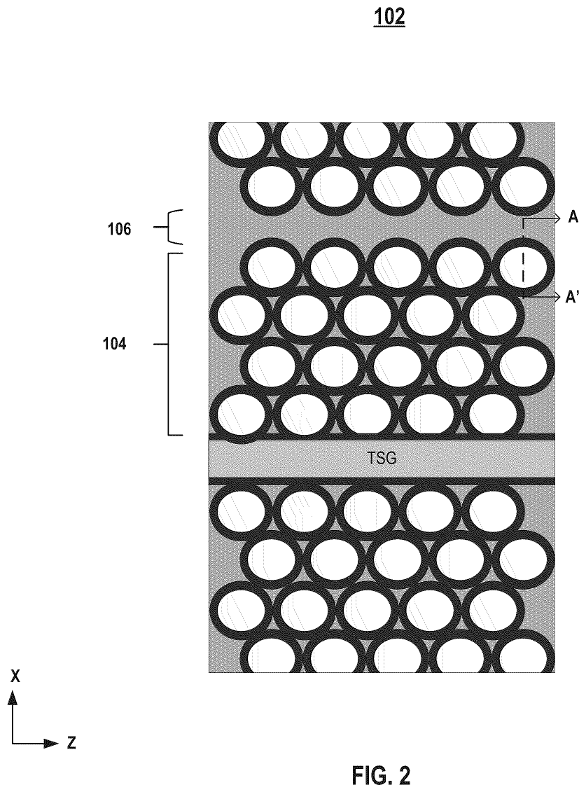

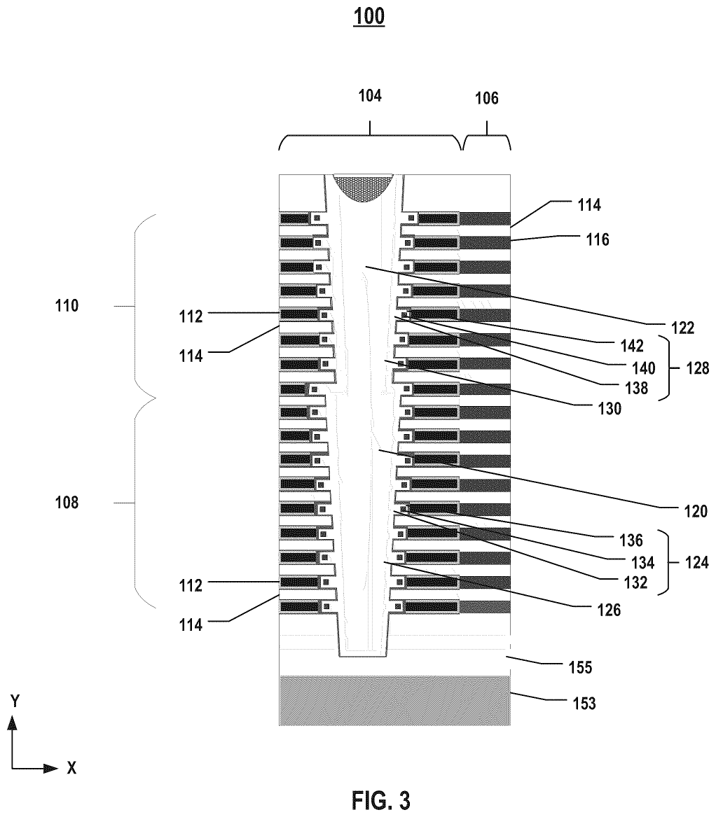

FIG. 2 illustrates another plan view of a region 102 of 3D memory device 100, according to some aspects of the present disclosure. Region 102 includes a channel structure region 104 and separation structure 106. In some implementations, each memory blocks 101 may include one or more than one channel structure region 104. FIG. 3 illustrates a cross-section of region 102 of 3D memory device 100 along line AA′ in FIG. 2, according to some aspects of the present disclosure.

As shown in FIG. 3, 3D memory device 100 includes a memory deck 108 and a memory deck 110 disposed on memory deck 108. Memory deck 108 may include a plurality of conductor layers 112 and a plurality of dielectric layers 114 vertically interleaved along the y-direction. Similarly, memory deck 110 may include conductor layers 112 and dielectric layers 114 vertically interleaved along the y-direction as well. In some implementations, conductor layers 112 may form the word lines and may include conductive materials including, but not limited to, tungsten (W), cobalt (Co), copper (Cu), aluminum (Al), polysilicon, doped silicon, silicides, or any combination thereof. In some implementations, dielectric layers 114 may include dielectric materials including, but not limited to, silicon oxide, silicon oxynitride, or any combination thereof. Separation structure 106 may extend laterally along the y-direction and the z-direction to separate two adjacent memory blocks 101. Each separation structure 106 may include a dielectric stack including vertically interleaved dielectric layers 114 and dielectric layers 116. Dielectric layers 114 in separation structure 106 may extend along the x-direction to connect with dielectric layers 114 in memory deck 108 and memory deck 110. In other words, dielectric layers 114 in separation structure 106, memory deck 108, and memory deck 110 may be formed in the same process, e.g., the deposition process, and have the same material.

Dielectric layers 116 in separation structure 106 may be in contact with conductor layers 112 in memory deck 108 and memory deck 110. In some implementations, dielectric layers 116 in separation structure 106 may electrically isolate conductor layers 112 in memory block 101 with other conductor layers 112 in adjacent memory block 101. As a result, dielectric layers 114 and dielectric layers 116 may electrically isolate memory block 101 with adjacent memory block 101. Since memory blocks are separated by separation structure 106 in the x-direction, the gate line slit structures are not needed in 3D memory device 100, and the area of 3D memory device 100 can be reduced.

A channel structure 120 may extend through memory deck 108 along the y-direction, and a channel structure 122 may extend through memory deck 110 along the y-direction. In some implementations, channel structures 120 may include a semiconductor channel 126, and a memory film 124 formed over semiconductor channel 126, and channel structures 122 may include a semiconductor channel 130, and a memory film 128 formed over semiconductor channel 130. The meaning of “over” here, besides the explanation stated above, should be also interpreted “over” something from the top side or from the lateral side.

In some implementations, semiconductor channel 126 of channel structure 120 may be in contact with semiconductor channel 130 of channel structure 122. In some implementations, semiconductor channel 126 of channel structure 120 may be in direct contact with semiconductor channel 130 of channel structure 122. Memory film 124 and memory film 128 may be multilayer structures and are partial of elements to achieve the storage function in 3D memory device 100. Each of memory film 124 and memory film 128 may include a composite layer of silicon oxide/silicon oxynitride/silicon oxide (ONO). The ONO structure may be formed over the surface of the semiconductor channel, and the ONO structure (the memory film) is also located between semiconductor channels 126/130 and conductor layers 112, such as word lines. In some implementations, semiconductor channels 126/130 may include silicon, such as amorphous silicon, polysilicon, or single crystalline silicon. The word lines may serve as a control gate and is electrically or electronically coupled to memory film 124 and memory film 128 in response to a bias.

In some implementations, memory film 124 may include a tunneling layer 132 over a side or sides of semiconductor channel 126, a storage layer 134 over a side or sides of tunneling layer 132, and a blocking layer 136 over a side or sides of storage layer 134. In some implementations, storage layer 134 may be a continuous structure extending along the channel structure. However, in some implementations, storage layer 134 may be divided by dielectric layers 114 into a plurality of sections, as show in FIG. 3. In some implementations, memory film 128 may include a tunneling layer 138 over semiconductor channel 130, a storage layer 140 over tunneling layer 138, and a blocking layer 142 over storage layer 140. In some implementations, storage layer 140 may be a continuous structure extending along the channel structure. However, in some implementations, storage layer 140 may be divided by dielectric layers 114 into a plurality of sections, as shown in FIG. 3.

By performing the word line replacement operation through the channel holes instead of using the gate line slit structures to form the word lines, the gate line slit structures are not needed in 3D memory device 100. Since memory blocks are separated by separation structure 106 in the x-direction, the gate line slit structures are not needed in 3D memory device 100, and the area of separation structure 106 can be reduced. Hence, the size of 3D memory device 100 may be further reduced.

In some implementations, after forming channel structure 122, one or more removal operations may be performed to remove a substrate 153, a semiconductor layer 155, and a bottom portion of channel structure 122 to expose semiconductor channel 126. In some implementations, another semiconductor layer may be further formed covering the exposed semiconductor channel 126.

When using the gate line slit structures to perform the word line replacement operation, portions of dielectric layers 116 are removed through the gate line slit structures. The removal rate or the etching rate of dielectric layers 116 at different portions may be different, and the difference may depend on the position of dielectric layers 116, such as near the gate line slit structures openings or away from the gate line slit structures openings. For example, the portion of dielectric layers 116 near the gate line slit structures openings may be removed more than another portion of dielectric layers 116 away from the gate line slit structures openings. In other words, the cavities formed by removing portions of dielectric layers 116 may have different heights or widths caused by different distances from the gate line slit structures openings. In some situations, the portions of dielectric layers 116 away from the gate line slit structures openings may have residue.

In some implementations, by performing the word line replacement operation through the channel holes instead of using the gate line slit structures, the above-described disadvantages can be prevented. In some implementations, conductor layers 112 may include a first portion near separation structure 106 and a second portion away from separation structure 106, and the first portion and the second portion may have a same thickness. In some implementations, dielectric layers 114 may include a first portion near separation structure 106 and a second portion away from separation structure 106, and a thickness different between the first portion and the second portion of dielectric layers 114 may be less than 1 nanometer. In some implementations, the thickness different between the first portion and the second portion of dielectric layers 114 may be less than 0.8 nanometer. In some implementations, the thickness different between the first portion and the second portion of dielectric layers 114 may be less than 0.6 nanometer. In some implementations, the thickness different between the first portion and the second portion of dielectric layers 114 may be less than 0.4 nanometer. In some implementations, the thickness of the first portion and the second portion of dielectric layers 114 may be the same.

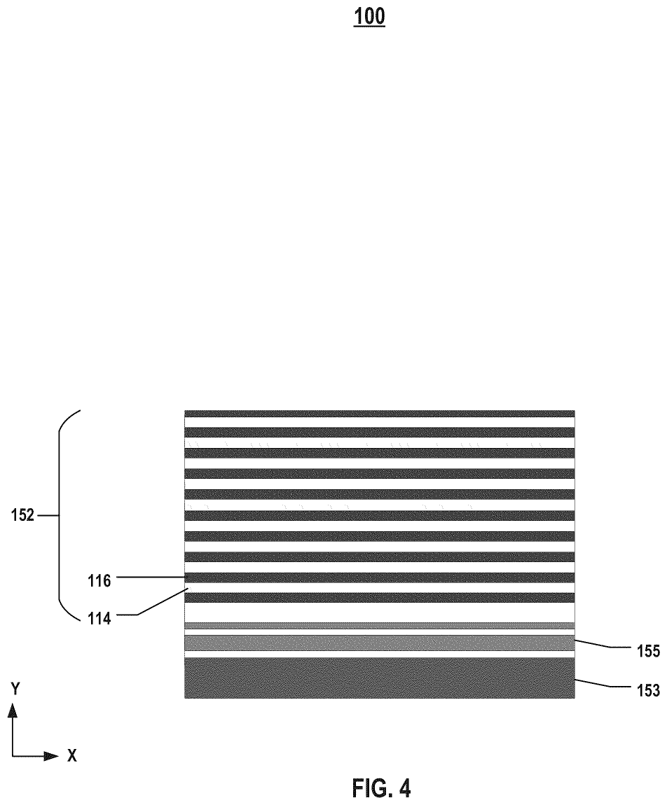

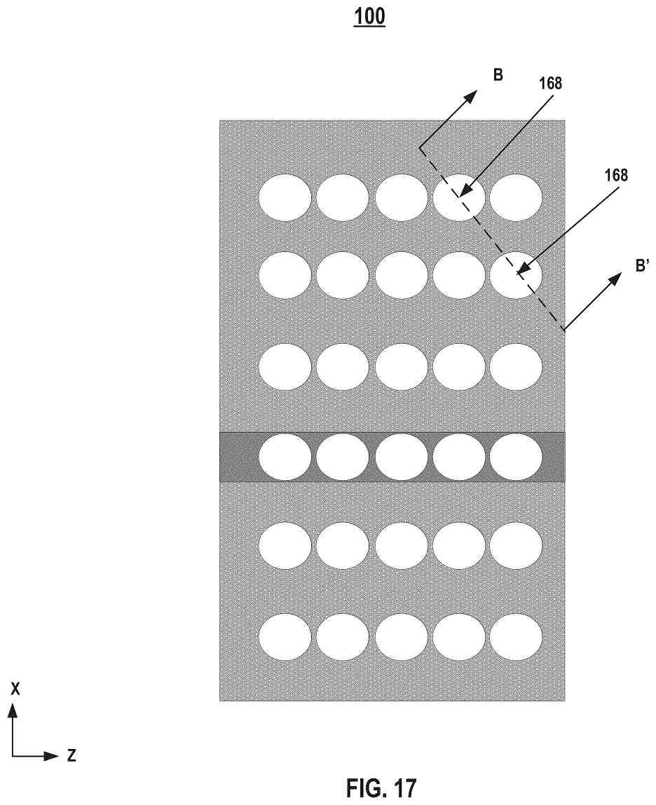

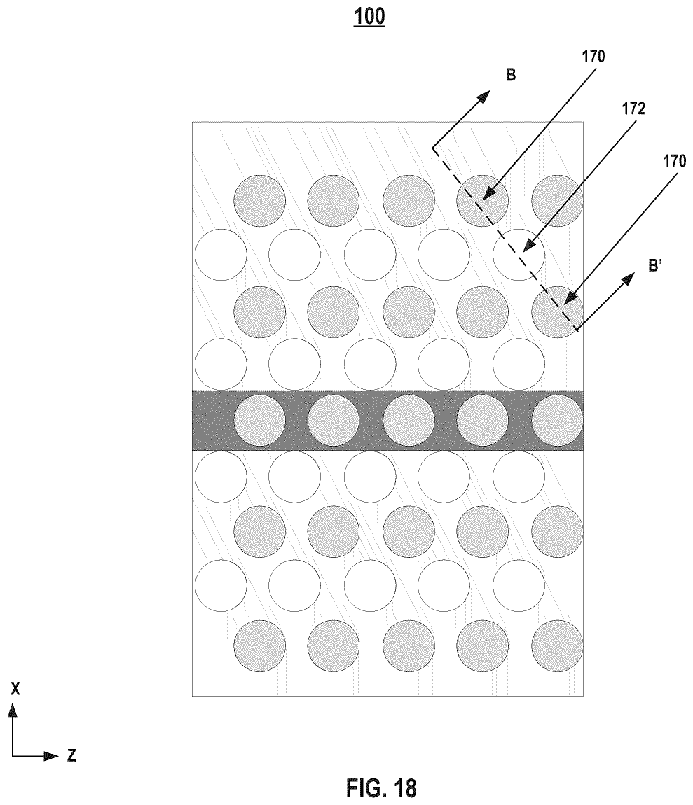

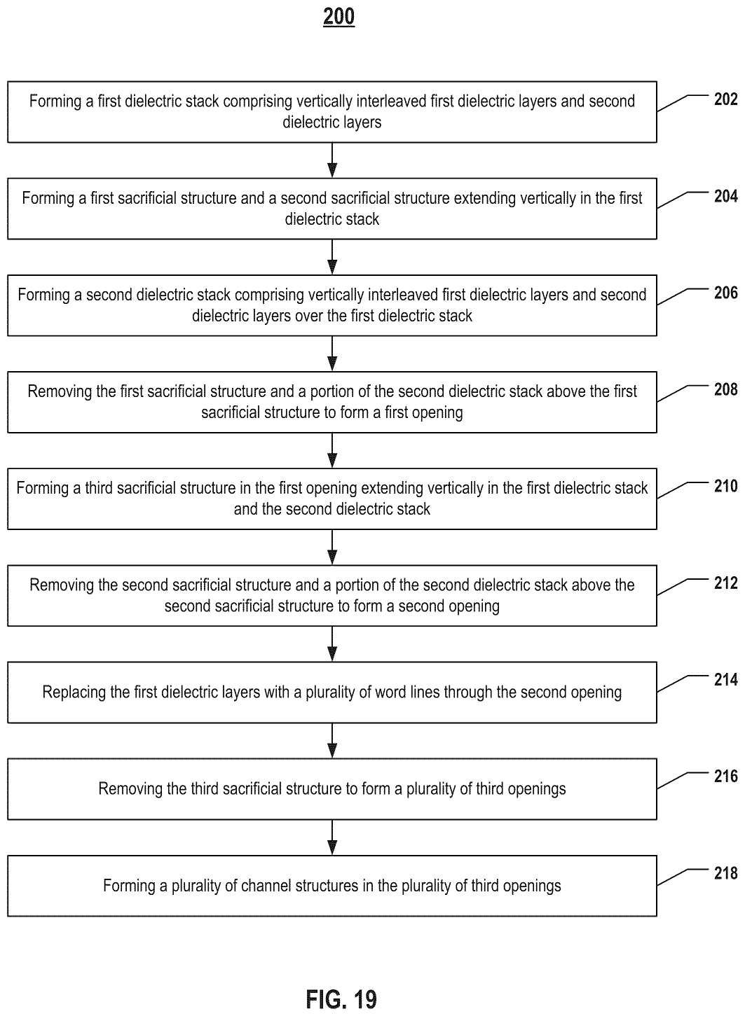

FIGS. 4-16 illustrate cross-sections of 3D memory device 100 along the x-direction and the y-direction at different stages of a manufacturing process, according to some aspects of the present disclosure. FIGS. 17-18 illustrate plan views of 3D memory device 100 at different stages of a manufacturing process, according to some aspects of the present disclosure. FIG. 19 illustrates a flowchart of an exemplary method 200 for forming 3D memory device 100, according to some aspects of the present disclosure.

For the purpose of better describing the present disclosure, the cross-sections of 3D memory device 100 in FIGS. 4-16, the plan views of 3D memory device 100 in FIGS. 17-18, and method 200 in FIG. 19 will be discussed together. It is understood that the operations shown in method 200 are not exhaustive and that other operations may be performed as well before, after, or between any of the illustrated operations. Further, some of the operations may be performed simultaneously, or in a different order than shown in FIGS. 4-16, 17-18, and 19.

As shown in FIG. 4 and operation 202 in FIG. 19, a dielectric stack 152 is formed. Dielectric stack 152 may include interleaved dielectric layers 116 and dielectric layers 114 along the y-direction. In some implementations, dielectric stack 152 is formed on a substrate 153. In some implementations, a semiconductor layer 155 is formed on substrate 153, and dielectric stack 152 is formed over semiconductor layer 155. In some implementations, substrate 153 may be a doped semiconductor layer. In some implementations, substrate 153 may be a silicon substrate. In some implementations, semiconductor layer 155 may be a doped or undoped polysilicon layer. In some implementations, dielectric layers 114 may include silicon oxide layers, and dielectric layers 116 may include silicon nitride layers. In some implementations, semiconductor layer 155, dielectric layers 114, and dielectric layers 116 may be sequentially deposited by one or more thin film deposition processes including, but not limited to, chemical vapor deposition (CVD), physical vapor deposition (PVD), atomic layer deposition (ALD), or any combination thereof.

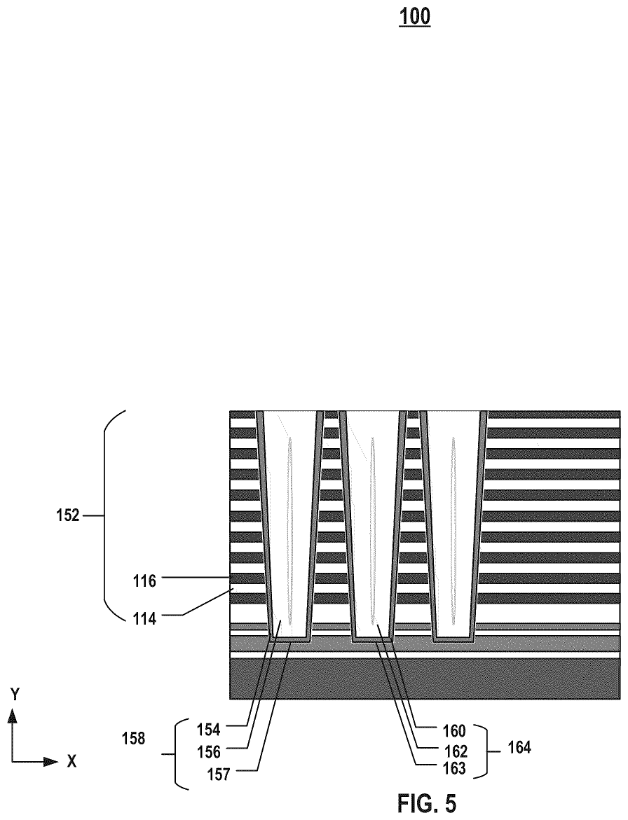

As shown in FIG. 5 and operation 204 in FIG. 19, a sacrificial structure 158 and a sacrificial structure 164 are formed in dielectric stack 152 extending vertically. In some implementations, openings may be formed extending in dielectric stack 152, and sacrificial structure 158 and sacrificial structure 164 may be formed in the openings. In some implementations, sacrificial structure 158 may include a dielectric layer 157, a semiconductor layer 154, and a dielectric layer 156 sequentially formed in the opening, and sacrificial structure 164 may include a dielectric layer 163, a semiconductor layer 160, and a dielectric layer 162 sequentially formed in the opening. In some implementations, dielectric layer 157 may include silicon oxide, semiconductor layer 154 may include polysilicon, dielectric layer 156 may include silicon oxide, dielectric layer 163 may include silicon oxide, semiconductor layer 160 may include polysilicon, and dielectric layer 162 may include silicon oxide.

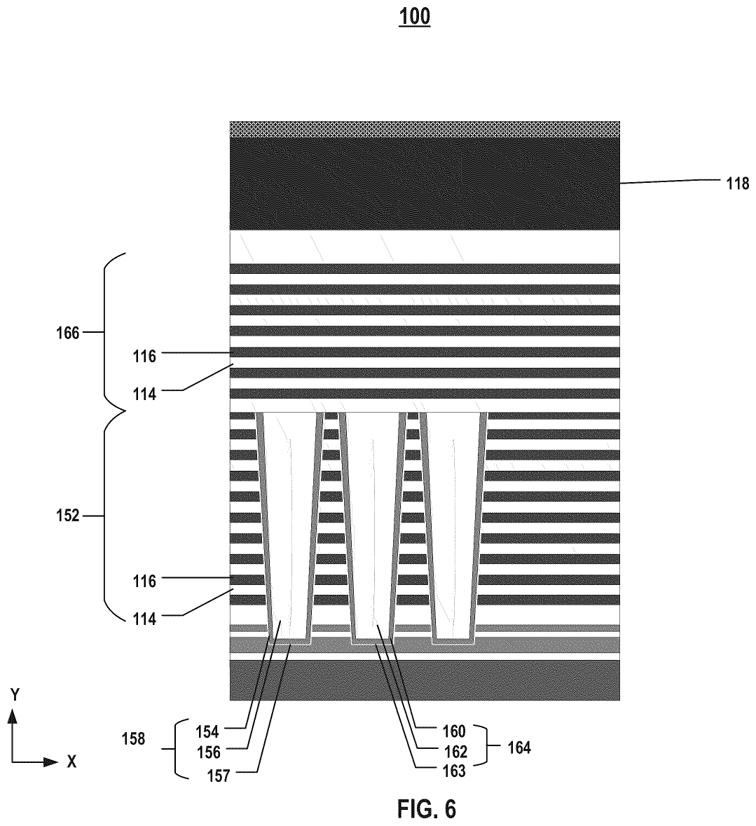

Then, as shown in FIG. 6 and operation 206 in FIG. 19, a dielectric stack 166 is formed on dielectric stack 152. In some implementations, dielectric stack 166 may have the same structure and may be formed by the same materials with dielectric stack 152. In some implementations, dielectric stack 166 may include vertically interleaved dielectric layers 114 and dielectric layers 116. In some implementations, a mask layer 118 may be further formed on dielectric stack 166 for forming the hard etching mask in the later operations.

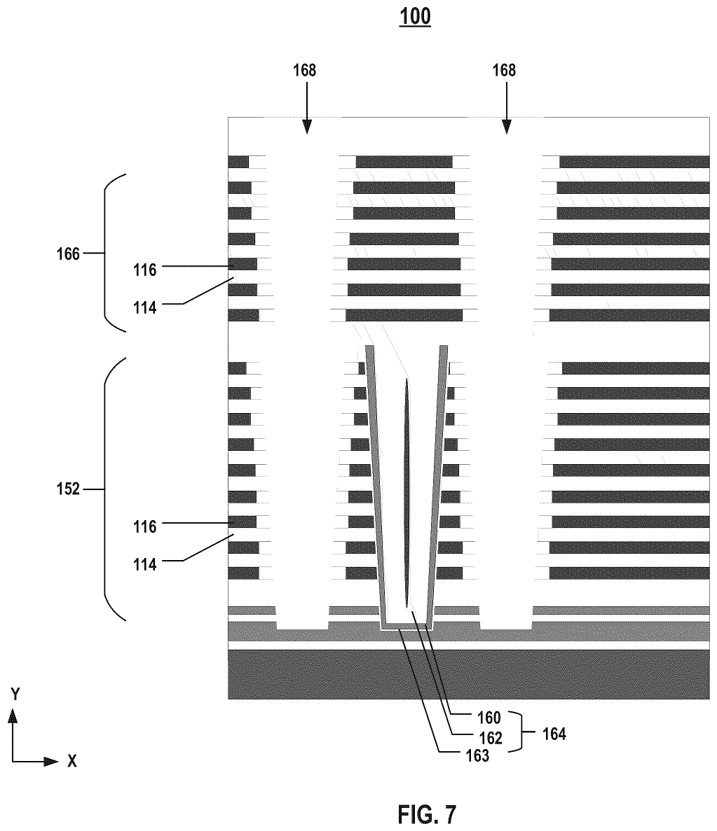

As shown in FIG. 7 and operation 208 in FIG. 19, sacrificial structure 158 and a portion of dielectric stack 166 above sacrificial structure 158 are removed to form an opening 168. In some implementations, mask layer 118 may be first formed a pattern for the etching operation, and the pattern is aligned to sacrificial structure 158. The etching operation may be performed to remove a portion of dielectric stack 166 above sacrificial structure 158 and remove sacrificial structure 158. In some implementations, the etching operation may include multiple process procedures. In some implementations, the etching operation may include wet etch, dry etch, or other suitable processes. In some implementations, the etching operation may have different etching selectivity to dielectric layers 114 and dielectric layers 116. In some implementations, a further removal operation, e.g., an etching process, may be performed to recess dielectric layers 116, and dielectric layers 116 may have concaves along the sidewalls of opening 168, as shown in FIG. 7. In some implementations, the concaves along the sidewalls may be used to form the divided trap layers in a later operation. In some implementations, opening 168 and/or opening 172 may be used for the replacing operation to form the word lines in the later operations, the concaves along the sidewalls of opening 168 and/or opening 172 may make the memory layers formed in the later operations having a same structure.

FIG. 17 illustrates the plan view of 3D memory device 100 after performing operation 208, according to some aspects of the present disclosure. FIG. 7 may illustrate the cross-section of 3D memory device 100 along line BB′ in FIG. 17. It is understood that the structure shown in FIG. 7 is for illustration only. In some implementations, one or more than one sacrificial structure 164 may be designed between two adjacent openings 168.

It is noted that, in FIGS. 7-9, two openings 168 is formed first and then opening 170 is formed between two sacrificial structures 170. However, in some implementations, opening 170 may be formed first and be filled with sacrificial structure 175, and then two openings 168 is formed at two sides of sacrificial structure 175. In some implementations, other suitable operations or orders may be applied to form sacrificial structures 170 and sacrificial structures 175, which are not limited in the application.

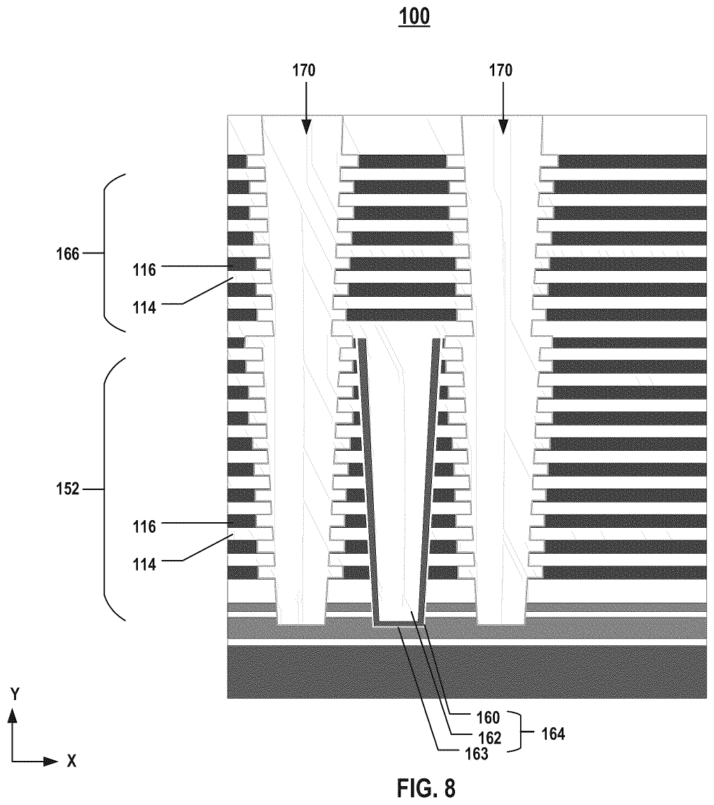

As shown in FIG. 8 and operation 210 in FIG. 19, a sacrificial structure 170 is formed in opening 168 extending vertically in dielectric stack 152 and dielectric stack 166. In some implementations, sacrificial structure 170 may be a multilayer structure. In some implementations, forming sacrificial structure 170 may include sequentially forming a dielectric layer, a semiconductor layer, and a dielectric layer in opening 168. In some implementations, forming sacrificial structure 170 may include sequentially forming a silicon oxide layer, a polysilicon layer, and a silicon oxide layer in opening 168. In some implementations, a removal operation, e.g., a chemical mechanical polishing (CMP) process, may be further performed to planarize the top surface.

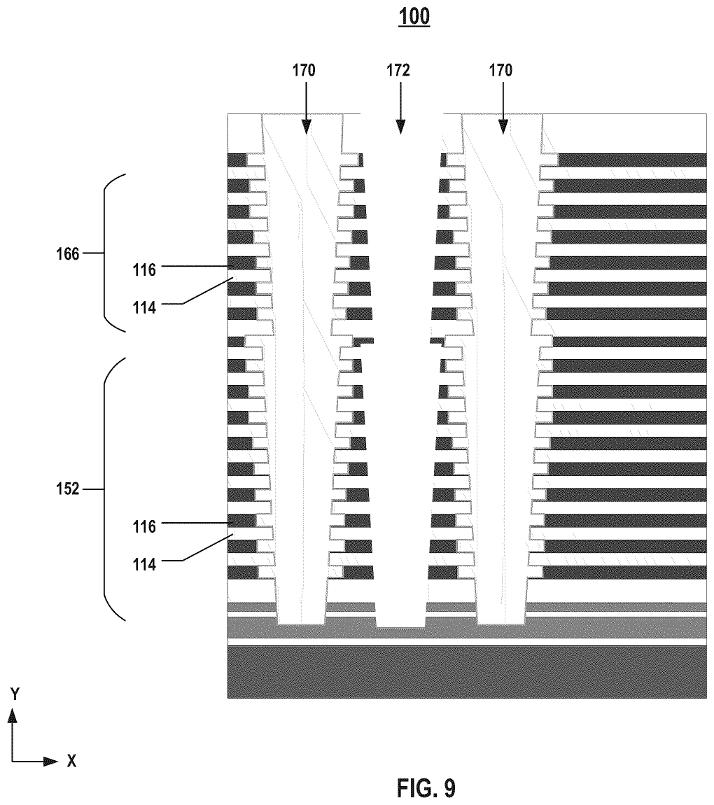

As shown in FIG. 9 and operation 212 in FIG. 19, a portion of dielectric stack 166 above and aligned sacrificial structure 164 is removed, and then sacrificial structure 164 is removed to form an opening 172. In some implementations, the portion of dielectric stack 166 above and aligned sacrificial structure 164 and sacrificial structure 164 may be removed by one or more than one etching operation. In some implementations, the etching operations may include wet etch, dry etch, or other suitable processes.

FIG. 18 illustrates the plan view of 3D memory device 100 after performing operation 212, according to some aspects of the present disclosure. FIG. 9 may illustrate the cross-section of 3D memory device 100 along line BB′ in FIG. 18.

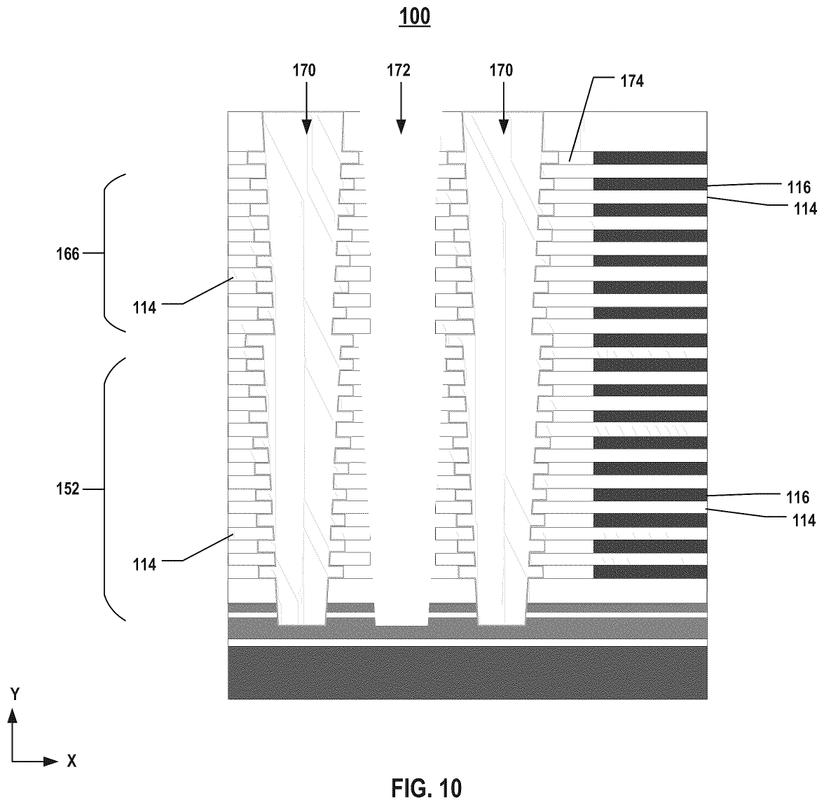

As shown in FIG. 10 and operation 214 in FIG. 19, portions of dielectric layers 116 may be removed and replaced with a plurality of word lines, e.g., conductor layers 112, through opening 172. In some implementations, portions of dielectric layers 116 may be removed through opening 172 to form cavities 174 in dielectric stack 152 and dielectric stack 166, as shown in FIG. 10. In some implementations, dielectric layers 116 near opening 172 are removed, and other portions of dielectric layers 116 far away from opening 172 remain. The remained portions of dielectric layers 116 may be used as a portion of separation structure 106 formed in the later operations.

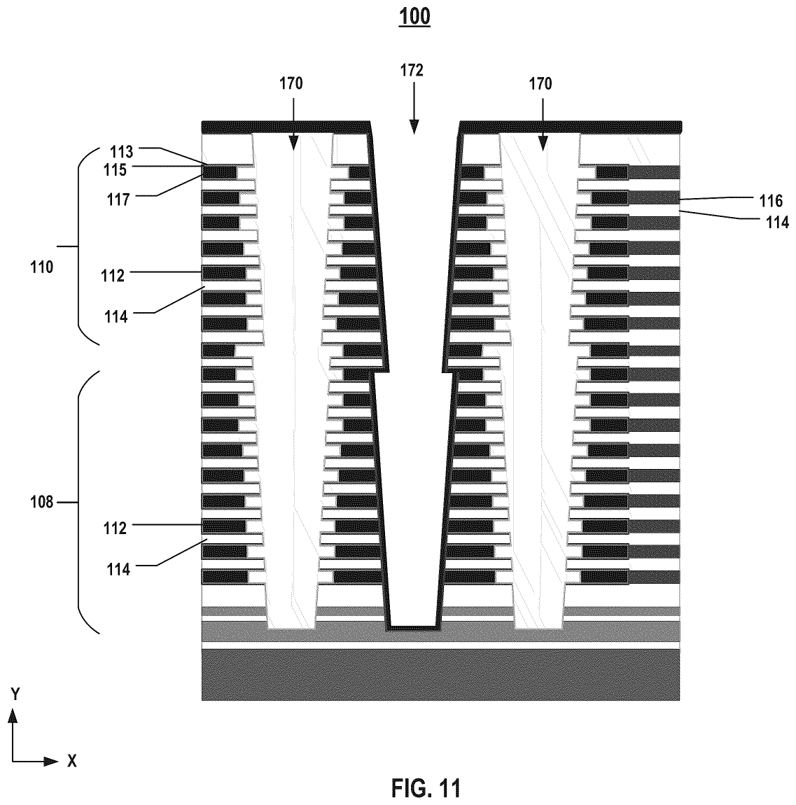

Then, as shown in FIG. 11, word lines are formed in cavities 174. In some implementations, each word line may be a multilayer structure. In some implementations, forming word lines may include sequentially forming a dielectric layer, a barrier layer, and a conductor layer in cavities 174. In some implementations, forming word lines may include sequentially forming a high dielectric constant (high-k) dielectric layer 113, a titanium nitride (TiN) layer 115, and a tungsten (W) layer 117 in cavities 174. The dielectric layer, the barrier layer, and the conductor layer formed on sidewalls of opening 172 may be then removed.

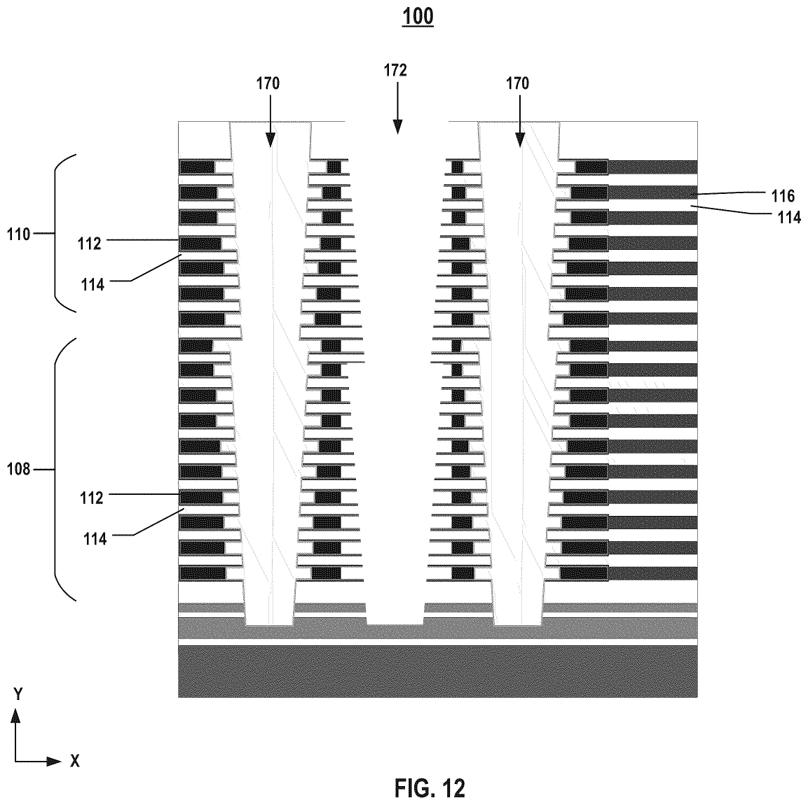

In some implementations, after removing the dielectric layer, the barrier layer, and the conductor layer on sidewalls of opening 172, further removal operations and deposition operations may be performed on word lines through opening 172. In some implementations, the removal operations may remove portions of conductor layer, e.g., W, through opening 172 to form a recessed structure, as shown in FIG. 12. In some implementations, the deposition operations may form the barrier layer, e.g., TiN, on the exposed conductor layer, e.g., W. In some implementations, a removal operation may be further performed to remove the redundant barrier layer. Then, the dielectric layer, e.g., a high-k dielectric layer, not covered by the barrier layer will be removed. In other words, the conductor layer may be surrounded by the barrier layer.

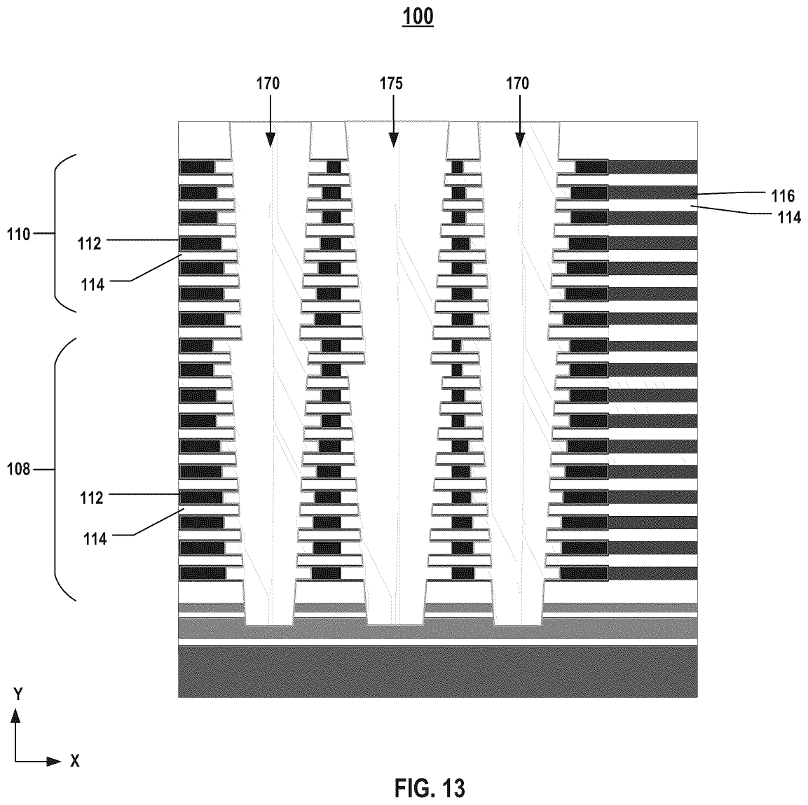

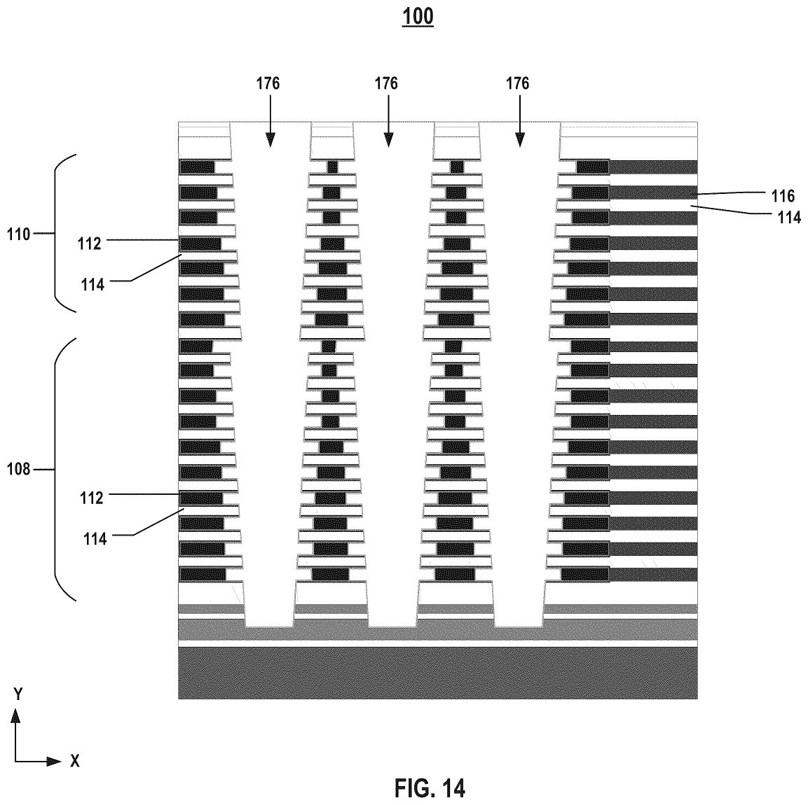

As shown in FIG. 13, FIG. 14, and operation 216 in FIG. 19, sacrificial structure 170 is removed to form a plurality of openings 176. In some implementations, a sacrificial structure 175 may be formed in opening 172 extending in memory deck 108 and memory deck 110, as shown in FIG. 13. It is understood that after the word line replacement operation, dielectric stack 152 and dielectric stack 166 may be called memory deck 108 and memory deck 110 as well. The structure and the materials of sacrificial structure 175 may be the same as sacrificial structure 170. Then, sacrificial structure 170 and sacrificial structure 175 may be removed together to form openings 176, as shown in FIG. 14. In some implementations, sacrificial structure 170 and sacrificial structure 175 are removed to form openings 176 first, the exposed high-k dielectric layer 113 is then removed, and another high-k dielectric layer is further formed on exposed sidewalls of the openings 176.

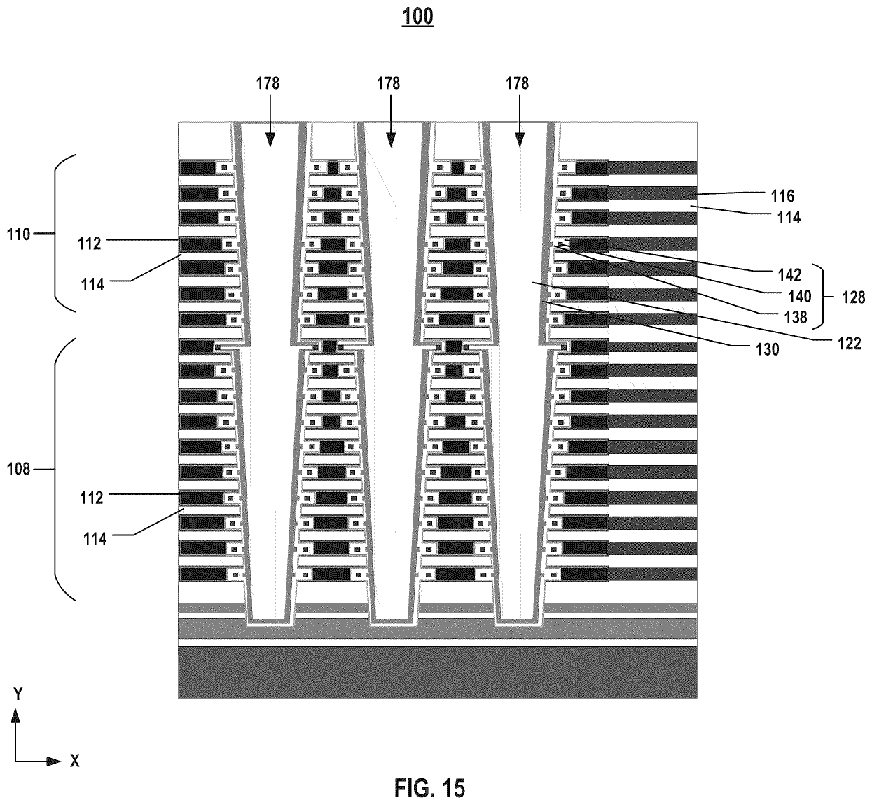

As shown in FIG. 15 and operation 218 in FIG. 19, channel structures 178 may be formed in openings 176. In some implementations, before forming channel structures 178, a removal operation may be performed to remove the high-k dielectric layer in the recess of sidewalls of openings 176, and a deposition operation may be performed to form a high-k dielectric layer on sidewalls of openings 176. In some implementations, forming channel structures 178 in openings 176 may include sequentially forming blocking layer 142, storage layer 140, tunneling layer 138, and semiconductor channel 130 in openings 176.

In some implementations, as shown in FIG. 15, storage layer 140 may be divided into a plurality of isolated sections along the y-direction. By dividing storage layer 140 into a plurality of isolated sections along the y-direction, memory film 128 is divided into several inconsecutive sections. The charge stored in storage layer 140 is isolated from other storage layers 140 corresponding to different word lines. In other words, the charge stored in storage layer 140 corresponding to different word lines is isolated from each other. Hence, the charge migration may be prevented in 3D memory device 100. In some implementations, since memory film 128 in a same channel is divided into several inconsecutive sections, the disturbance and electron migration between different cells may be prevented, and the sum of the charge between different cells may be improved.

In some implementations, blocking layer 142 is formed in recesses on sidewalls of openings 176. In some implementations, blocking layer 142 may include silicon oxide, silicon oxynitride, high-k dielectrics, or any combination thereof. In some implementations, blocking layer 142 may be formed by a deposition operation.

Storage layer 140 may be formed over blocking layer 142 in the recesses. Storage layer 140 in each recess is separated by dielectric layers 114. In some implementations, storage layer 140 is first conformally formed on the sidewalls of openings 176 covering dielectric layers 114 and blocking layer 142. Then, an etch operation may be performed to pull back a portion of storage layer 140. In some implementations, the portion of storage layer 140 may be removed by dry etch, wet etch, or other suitable processes. After the pull-back process, storage layer 140 is divided by dielectric layers 114 into a plurality of isolated sections.

Tunneling layer 138 is formed over storage layer 140 and dielectric layers 114 on the sidewalls of openings 176. In some implementations, tunneling layer 138 may further be thinned by performing an etch operation. In some implementations, tunneling layer 138 may further be thinned until tunneling layer 138 is fully isolated by dielectric layers 114. In some implementations, blocking layer 142 may further be thinned until tunneling layer 138 is fully isolated by dielectric layers 114. In some implementations, tunneling layer 138 may not be fully isolated by dielectric layers 114 after the thinning operation. In some implementations, tunneling layer 138 may be continuously disposed along the y-direction. Semiconductor channel 130 is formed over tunneling layer 138. In some implementations, semiconductor channel 130 may be in direct contact with dielectric layers 114. In some implementations, a dielectric core may be formed to fill in openings 176.

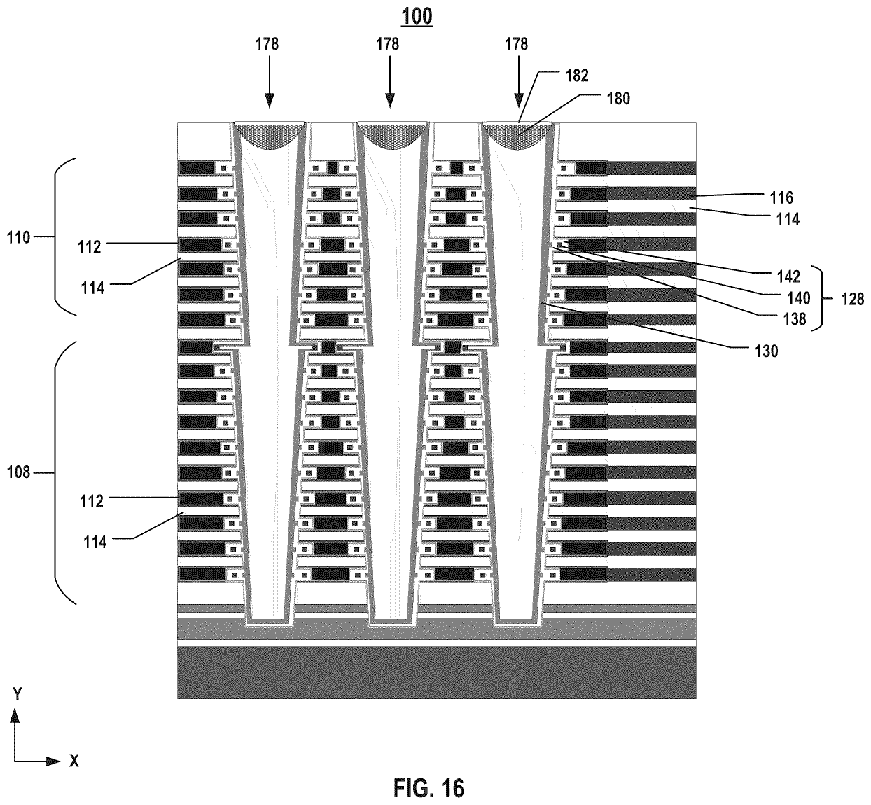

In some implementations, as shown in FIG. 16, a plug polysilicon 180 may be formed on the top of each channel structure 178. In some implementations, a recess may be first formed on the top of each channel structure 178 by performing an etching operation. A deposition operation may be then performed to form a polysilicon layer in the recess, and a planarization operation may be performed to remove the extra polysilicon layer and form plug polysilicon 180 in the recess. In some implementation, an implantation operation may be performed on plug polysilicon 180 to form an implanted plug 182.

In some implementations, one or more removal operations may be further performed to remove substrate 153, semiconductor layer 155, and a bottom portion the channel structure to expose semiconductor channel 126/130. In some implementations, another semiconductor layer may be further formed covering the exposed semiconductor channel 126/130.

By performing the word line replacement operation through the channel holes instead of using the gate line slit structures to form the word lines, the gate line slit structures are not needed in 3D memory device 100. Since memory blocks are separated by separation structure 106 in the x-direction, the gate line slit structures are not needed in 3D memory device 100, and the area of separation structure 106 can be reduced. Hence, the size of 3D memory device 100 may be further reduced.

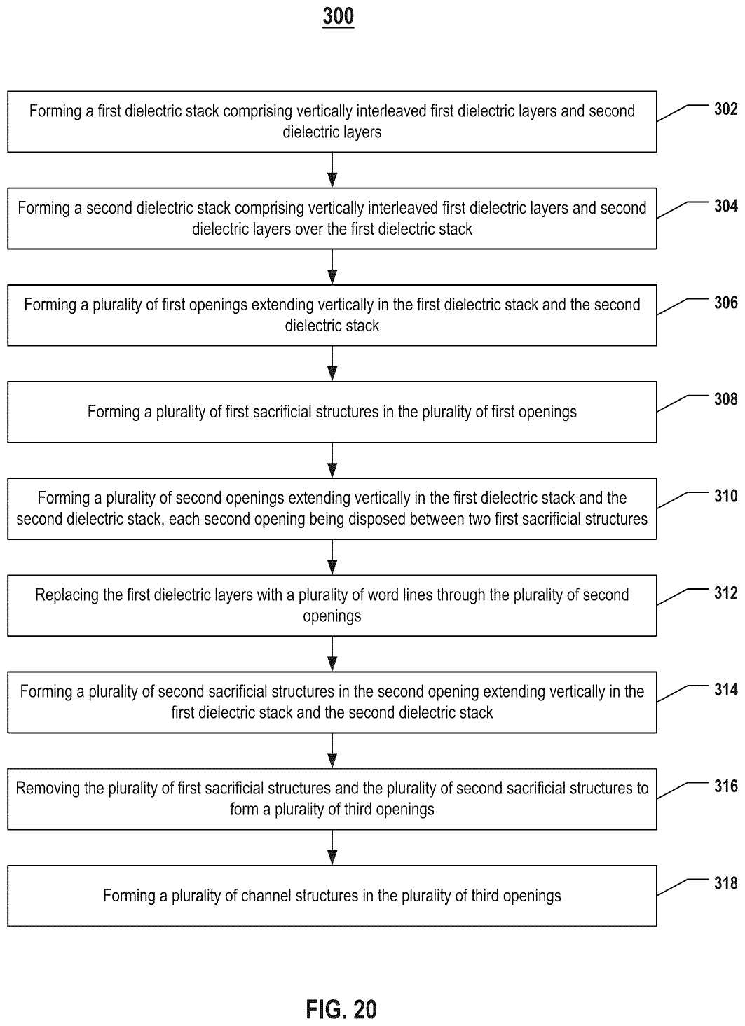

FIG. 20 illustrates a flowchart of another exemplary method 300 for forming 3D memory device 100, according to some aspects of the present disclosure. As shown in operation 302, dielectric stack 152 is formed. Dielectric stack 152 may include interleaved dielectric layers 116 and dielectric layers 114 along the y-direction. In some implementations, dielectric stack 152 is formed over substrate 153. In some implementations, semiconductor layer 155 is formed on substrate 153, and dielectric stack 152 is formed on semiconductor layer 155. In some implementations, substrate 153 may be a doped semiconductor layer. In some implementations, substrate 153 may be a silicon substrate. In some implementations, semiconductor layer 155 may be a doped or undoped polysilicon layer. In some implementations, dielectric layers 114 may include silicon oxide layers, and dielectric layers 116 may include silicon nitride layers. In some implementations, semiconductor layer 155, dielectric layers 114, and dielectric layers 116 may be sequentially deposited by one or more thin film deposition processes including, but not limited to, CVD, PVD, ALD, or any combination thereof.

In some implementations, sacrificial structure 158 and sacrificial structure 164 are formed in dielectric stack 152 extending vertically. In some implementations, the openings may be formed extending in dielectric stack 152, and sacrificial structure 158 and sacrificial structure 164 may be formed in the openings. In some implementations, sacrificial structure 158 may include a dielectric layer 157, a semiconductor layer 154, and a dielectric layer 156 sequentially formed in the opening, and sacrificial structure 164 may include a dielectric layer 163, a semiconductor layer 160, and a dielectric layer 162 sequentially formed in the opening. In some implementations, dielectric layer 157 may include silicon oxide, semiconductor layer 154 may include polysilicon, dielectric layer 156 may include silicon oxide, dielectric layer 163 may include silicon oxide, semiconductor layer 160 may include polysilicon, and dielectric layer 162 may include silicon oxide.

As shown in operation 304, dielectric stack 166 is formed on dielectric stack 152. In some implementations, dielectric stack 166 may have the same structure and may be formed by the same materials with dielectric stack 152. In some implementations, dielectric stack 166 may include vertically interleaved dielectric layers 114 and dielectric layers 116.

As shown in operation 306, a plurality of openings 168 are formed extending vertically in dielectric stack 152 and dielectric stack 166. In some implementations, sacrificial structure 158 and a portion of dielectric stack 166 above sacrificial structure 158 are removed to form an opening 168. In some implementations, mask layer 118 may be first formed a pattern for the etching operation, and the pattern is aligned to sacrificial structure 158. The etching operation may be performed to remove a portion of dielectric stack 166 above sacrificial structure 158 and remove sacrificial structure 158. In some implementations, the etching operation may include multiple process procedures. In some implementations, the etching operation may include wet etch, dry etch, or other suitable processes. In some implementations, the etching operation may have different etching selectivity to dielectric layers 114 and dielectric layers 116. In some implementations, a further removal operation, e.g., an etching process, may be performed to recess dielectric layers 116, and dielectric layers 116 may have concaves along the sidewalls of opening 168.

As shown in operation 308, sacrificial structures 170 are formed in openings 168 extending in dielectric stack 152 and dielectric stack 166. In some implementations, sacrificial structure 170 may be a multilayer structure. In some implementations, forming sacrificial structure 170 may include sequentially forming a dielectric layer, a semiconductor layer, and a dielectric layer in opening 168. In some implementations, forming sacrificial structure 170 may include sequentially forming a silicon oxide layer, a polysilicon layer, and a silicon oxide layer in opening 168.

As shown in operation 310, a plurality of openings 172 are formed extending in dielectric stack 152 and dielectric stack 166, and each opening 172 is formed between two sacrificial structures 170. In some implementations, the portion of dielectric stack 166 above and aligned sacrificial structure 164 and sacrificial structure 164 may be removed by one or more than one etching operation. In some implementations, the etching operations may include wet etch, dry etch, or other suitable processes.

As shown in operation 312, dielectric layers 116 are replaced with word lines, e.g., conductor layers 112, through the plurality of openings 172. In some implementations, portions of dielectric layers 116 may be removed through opening 172 to form cavities 174 in dielectric stack 152 and dielectric stack 166. In some implementations, dielectric layers 116 near opening 172 are removed, and other portions of dielectric layers 116 far away from opening 172 remain. The remained portions of dielectric layers 116 may be used as a portion of separation structure 106 formed in the later operations.

Then, word lines are formed in cavities 174. In some implementations, each word line may be a multilayer structure. In some implementations, forming word lines may include sequentially forming a dielectric layer, a barrier layer, and a conductor layer in cavities 174. In some implementations, forming word lines may include sequentially forming a high-k dielectric layer, a TiN layer, and a W layer in cavities 174. The dielectric layer, the barrier layer, and the conductor layer formed on sidewalls of opening 172 may be then removed.

In some implementations, after removing the dielectric layer, the barrier layer, and the conductor layer on sidewalls of opening 172, further removal operations and deposition operations may be performed on word lines through opening 172. In some implementations, the removal operations may remove portions of the conductor layer, e.g., W, through opening 172 to form a recessed structure. In some implementations, the deposition operations may form the barrier layer, e.g., TiN, on the exposed conductor layer, e.g., W. In some implementations, a removal operation may be further performed to remove the redundant barrier layer. Then, the dielectric layer, e.g., a high-k dielectric layer, not covered by the barrier layer will be removed. In other words, the conductor layer may be surrounded by the barrier layer in a cross-sectional view of 3D memory device 100.

As shown in operation 314, sacrificial structures 175 are formed in openings 172 extending in dielectric stack 152 and dielectric stack 166. It is understood that after the word line replacement operation, dielectric stack 152 and dielectric stack 166 may be called memory deck 108 and memory deck 110 as well. As shown in operation 316, sacrificial structures 170 and sacrificial structures 175 are removed to form openings 176.

As shown in operation 318, channel structures 178 are formed in openings 176. In some implementations, before forming channel structures 178, a removal operation may be performed to remove the high-k dielectric layer in the recess of sidewalls of openings 176, and a deposition operation may be performed to form a high-k dielectric layer on sidewalls of openings 176. In some implementations, forming channel structures 178 in openings 176 may include sequentially forming blocking layer 142, storage layer 140, tunneling layer 138, and semiconductor channel 130 in openings 176.

In some implementations, storage layer 140 may be divided into a plurality of isolated sections along the y-direction. By dividing storage layer 140 into a plurality of isolated sections along the y-direction, memory film 128 is divided into several inconsecutive sections. The charge stored in storage layer 140 is isolated from other storage layers 140 corresponding to different word lines. In other words, the charge stored in storage layer 140 corresponding to different word lines is isolated from each other. Hence, the charge migration may be prevented in 3D memory device 100.

In some implementations, blocking layer 142 is formed in recesses on sidewalls of openings 176. In some implementations, blocking layer 142 may include silicon oxide, silicon oxynitride, high-k dielectrics, or any combination thereof. In some implementations, blocking layer 142 may be formed by a deposition operation.

Storage layer 140 may be formed over blocking layer 142 in the recesses. Storage layer 140 in each recess is separated by dielectric layers 114. In some implementations, storage layer 140 is first conformally formed on the sidewalls of openings 176 covering dielectric layers 114 and blocking layer 142. Then, an etch operation may be performed to pull back a portion of storage layer 140. In some implementations, the portion of storage layer 140 may be removed by dry etch, wet etch, or other suitable processes. After the pull-back process, storage layer 140 is divided by dielectric layers 114 into a plurality of isolated sections.

Tunneling layer 138 is formed over storage layer 140 and dielectric layers 114 on the sidewalls of openings 176. In some implementations, tunneling layer 138 may further be thinned by performing an etch operation. In some implementations, tunneling layer 138 may further be thinned until tunneling layer 138 is fully isolated by dielectric layers 114. In some implementations, tunneling layer 138 may not be fully isolated by dielectric layers 114 after the thinning operation. In some implementations, tunneling layer 138 may be continuously disposed along the y-direction. Semiconductor channel 130 is formed over tunneling layer 138. In some implementations, semiconductor channel 130 may be in direct contact with dielectric layers 114. In some implementations, the dielectric core may be formed to fill in openings 176.

In some implementations, one or more removal operations may be further performed to remove substrate 153, semiconductor layer 155, and a bottom portion the channel structure to expose semiconductor channel 126/130. In some implementations, another semiconductor layer may be further formed covering the exposed semiconductor channel 126/130.

By performing the word line replacement operation through the channel holes instead of using the gate line slit structures to form the word lines, the gate line slit structures are not needed in 3D memory device 100. Since memory blocks are separated by separation structure 106 in the x-direction, the gate line slit structures are not needed in 3D memory device 100, and the area of separation structure 106 can be reduced. Hence, the size of 3D memory device 100 may be further reduced.

FIG. 21 illustrates a block diagram of an exemplary system 400 having a memory device, according to some aspects of the present disclosure. System 400 can be a mobile phone, a desktop computer, a laptop computer, a tablet, a vehicle computer, a gaming console, a printer, a positioning device, a wearable electronic device, a smart sensor, a virtual reality (VR) device, an argument reality (AR) device, or any other suitable electronic devices having storage therein. As shown in FIG. 21, system 400 can include a host 408 and a memory system 402 having one or more memory devices 404 and a memory controller 406. Host 408 can be a processor of an electronic device, such as a central processing unit (CPU), or a system-on-chip (SoC), such as an application processor (AP). Host 408 can be configured to send or receive data to or from memory devices 404.

Memory device 404 can be any memory device disclosed in the present disclosure. As disclosed above in detail, memory device 404, such as a NAND Flash memory device, may have a controlled and predefined discharge current in the discharge operation of discharging the bit lines. Memory controller 406 is coupled to memory device 404 and host 408 and is configured to control memory device 404, according to some implementations. Memory controller 406 can manage the data stored in memory device 404 and communicate with host 408. For example, memory controller 406 may be coupled to memory device 404, such as 3D memory device 100 described above, and memory controller 406 may be configured to control the operations of channel structures 178 through the peripheral device.

By performing the word line replacement operation through the channel holes instead of using the gate line slit structures to form the word lines, the gate line slit structures are not needed in 3D memory device 100. Since memory blocks are separated by separation structure 106 in the x-direction, the gate line slit structures are not needed in 3D memory device 100, and the area of separation structure 106 can be reduced. Hence, the size of 3D memory device 100 may be further reduced.

In some implementations, memory controller 406 is designed for operating in a low duty-cycle environment like secure digital (SD) cards, compact Flash (CF) cards, universal serial bus (USB) Flash drives, or other media for use in electronic devices, such as personal computers, digital cameras, mobile phones, etc. In some implementations, memory controller 406 is designed for operating in a high duty-cycle environment SSDs or embedded multi-media-cards (eMMCs) used as data storage for mobile devices, such as smartphones, tablets, laptop computers, etc., and enterprise storage arrays. Memory controller 406 can be configured to control operations of memory device 404, such as read, erase, and program operations. Memory controller 406 can also be configured to manage various functions with respect to the data stored or to be stored in memory device 404 including, but not limited to bad-block management, garbage collection, logical-to-physical address conversion, wear leveling, etc. In some implementations, memory controller 406 is further configured to process error correction codes (ECCs) with respect to the data read from or written to memory device 404. Any other suitable functions may be performed by memory controller 406 as well, for example, formatting memory device 404. Memory controller 406 can communicate with an external device (e.g., host 408) according to a particular communication protocol. For example, memory controller 406 may communicate with the external device through at least one of various interface protocols, such as a USB protocol, an MMC protocol, a peripheral component interconnection (PCI) protocol, a PCI-express (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a Firewire protocol, etc.

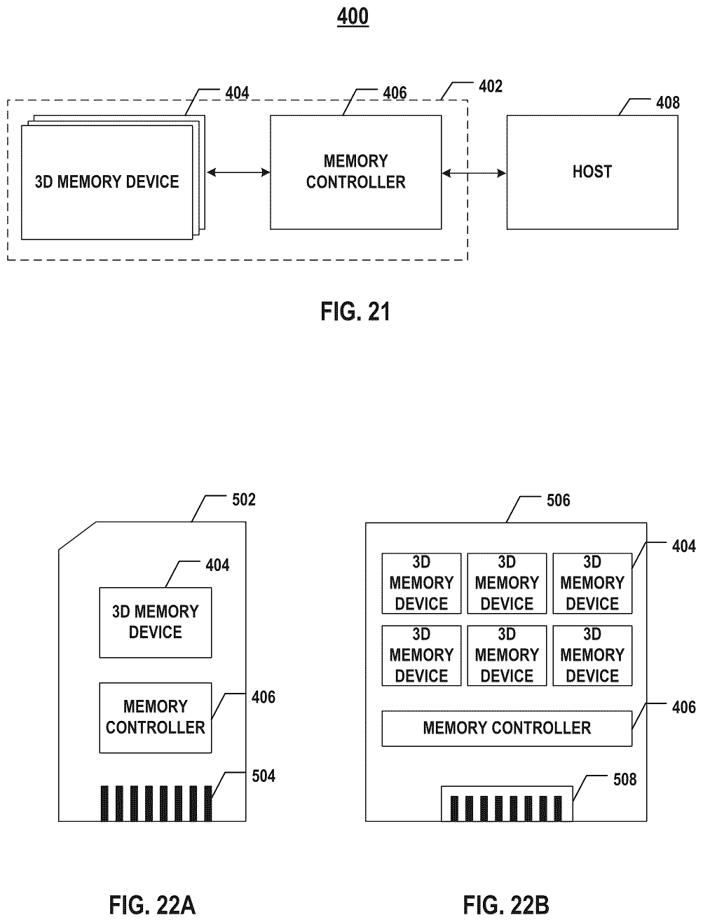

Memory controller 406 and one or more memory devices 404 can be integrated into various types of storage devices, for example, be included in the same package, such as a universal Flash storage (UFS) package or an eMMC package. That is, memory system 402 can be implemented and packaged into different types of end electronic products. In one example as shown in FIG. 22A, memory controller 406 and a single memory device 404 may be integrated into a memory card 502. Memory card 502 can include a PC card (PCMCIA, personal computer memory card international association), a CF card, a smart media (SM) card, a memory stick, a multimedia card (MMC, RS-MMC, MMCmicro), an SD card (SD, miniSD, microSD, SDHC), a UFS, etc. Memory card 502 can further include a memory card connector 504 coupling memory card 502 with a host (e.g., host 408 in FIG. 21). In another example as shown in FIG. 22B, memory controller 406 and multiple memory devices 404 may be integrated into an SSD 506. SSD 506 can further include an SSD connector 508 coupling SSD 506 with a host (e.g., host 408 in FIG. 21). In some implementations, the storage capacity and/or the operation speed of SSD 506 is greater than those of memory card 502.

The foregoing description of the specific implementations can be readily modified and/or adapted for various applications. Therefore, such adaptations and modifications are intended to be within the meaning and range of equivalents of the disclosed implementations, based on the teaching and guidance presented herein.

The breadth and scope of the present disclosure should not be limited by any of the above-described exemplary implementations, but should be defined only in accordance with the following claims and their equivalents.

What is claimed is:

1. A semiconductor device, comprising:
a plurality of memory blocks, each memory block comprising:
a memory deck comprising interleaved first conductor layers and first dielectric layers; and
a separation structure extending to separate two adjacent memory blocks, each separation structure comprising:
a dielectric stack comprising interleaved third dielectric layers and fourth dielectric layers,
wherein the third dielectric layers are in contact with the first dielectric layers, and the fourth dielectric layers are in contact with the first conductor layers.

2. The semiconductor device of claim 1, wherein the memory deck comprises:
a first memory deck comprising interleaved first conductor layers and first dielectric layers; and
a second memory deck comprising interleaved second conductor layers and second dielectric layers above the first memory deck.

3. The semiconductor device of claim 2, further comprising:
a first channel structure extending through the first memory deck, the first channel structure comprising a first memory film and a first semiconductor channel; and
a second channel structure extending through the second memory deck, the second channel structure comprising a second memory film and a second semiconductor channel, wherein the second semiconductor channel is in contact with the first semiconductor channel.

4. The semiconductor device of claim 3, wherein the first memory film comprises a tunneling layer over the first semiconductor channel, a storage layer over the tunneling layer, and a blocking layer over the storage layer,
wherein the storage layer is divided by the first dielectric layers into a plurality of sections.

5. The semiconductor device of claim 3, wherein the second memory film comprises a tunneling layer over the second semiconductor channel, a storage layer over the tunneling layer, and a blocking layer over the storage layer,
wherein the storage layer is divided by the second dielectric layers into a plurality of sections.

6. The semiconductor device of claim 1, further comprising:
a peripheral circuit disposed above or beneath the plurality of memory blocks.

7. The semiconductor device of claim 1, wherein the first conductor layers comprise a first portion near the separation structure and a second portion away from the separation structure, and the first portion and the second portion have a same thickness.

8. The semiconductor device of claim 1, wherein the first dielectric layers comprise a first portion near the separation structure and a second portion away from the separation structure, and a thickness different between the first portion and the second portion is less than 1 nanometer.

9. A method for forming a semiconductor device, comprising:
forming a dielectric stack comprising interleaved first dielectric layers and second dielectric layers;
forming a first opening extending in the dielectric stack;
replacing the first dielectric layers with a plurality of word lines through the first opening; and
forming a plurality of channel structures in the first opening.

10. The method of claim 9, wherein forming the dielectric stack comprising interleaved first dielectric layers and second dielectric layers, comprises:
forming a first dielectric stack comprising interleaved first dielectric layers and second dielectric layers;
forming a first sacrificial structure and a second sacrificial structure extending in the first dielectric stack; and
forming a second dielectric stack comprising interleaved first dielectric layers and second dielectric layers over the first dielectric stack.

11. The method of claim 9, wherein the dielectric stack comprises the first dielectric stack and the second dielectric stack.

12. The method of claim 9, wherein forming the first opening extending in the dielectric stack, comprises:
removing the first sacrificial structure and a portion of the second dielectric stack above the first sacrificial structure to form a second opening;
forming a third sacrificial structure in the first opening extending in the first dielectric stack and the second dielectric stack; and
removing the second sacrificial structure and a portion of the second dielectric stack above the second sacrificial structure to form the first opening.

13. The method of claim 12, further comprising:
removing the third sacrificial structure to form a plurality of third openings; and
forming the plurality of channel structures in the plurality of third openings.

14. The method of claim 9, wherein forming the first sacrificial structure and the second sacrificial structure extending in the first dielectric stack, comprises:
forming a fourth opening and a fifth opening extending in the first dielectric stack; and
forming a third dielectric layer, a first semiconductor layer and a fourth dielectric layer in the fourth opening and the fifth opening to form the first sacrificial structure and the second sacrificial structure.

15. The method of claim 14, wherein the third dielectric layer comprises a silicon oxide layer, the first semiconductor layer comprises a polysilicon layer, and the fourth dielectric layer comprises a silicon oxide layer.

16. The method of claim 12, wherein removing the first sacrificial structure and the portion of the second dielectric stack above the first sacrificial structure to form the first opening, comprises:
forming a patterned mask on the second dielectric stack aligning the first sacrificial structure;
removing the portion of the second dielectric stack above the first sacrificial structure; and
removing the first sacrificial structure.

17. The method of claim 12, wherein forming the third sacrificial structure in the first opening extending vertically in the first dielectric stack and the second dielectric stack, further comprises:
forming a fifth dielectric layer, a second semiconductor layer, and a sixth dielectric layer in the second opening.

18. A method for forming a semiconductor device, comprising:
forming a first dielectric stack comprising interleaved first dielectric layers and second dielectric layers;
forming a second dielectric stack comprising interleaved first dielectric layers and second dielectric layers over the first dielectric stack;
forming a plurality of first openings extending in the first dielectric stack and the second dielectric stack;
forming a plurality of first sacrificial structures in the plurality of first openings;
forming a plurality of second openings extending in the first dielectric stack and the second dielectric stack, each second opening being disposed between two first sacrificial structures;
replacing the first dielectric layers with a plurality of word lines through the plurality of second openings;
forming a plurality of second sacrificial structures in the second opening extending in the first dielectric stack and the second dielectric stack;
removing the plurality of first sacrificial structures and the plurality of second sacrificial structures to form a plurality of third openings; and
forming a plurality of channel structures in the plurality of third openings.

19. The method of claim 18, wherein forming the first dielectric stack comprising interleaved first dielectric layers and second dielectric layers, comprises:
forming a fourth opening and a fifth opening extending in the first dielectric stack; and
forming a first semiconductor layer and a third dielectric layer in the fourth opening and the fifth opening to form a third sacrificial structure and a fourth sacrificial structure extending in the first dielectric stack.

20. The method of claim 19, wherein the first semiconductor layer comprises a polysilicon layer, and the third dielectric layer comprises a silicon oxide layer.
